(19) United States
(12) Patent Application Publication
(10) Pub. No.: US 2012/0021581 A1
(43) Pub. Date: Jan. 26, 2012

(54) SELF-ALIGNED CONTACT STRUCTURE LATERALLY ENCLOSED BY AN ISOLATION STRUCTURE OF A SEMICONDUCTOR DEVICE

(75) Inventors: Thomas Werner, Reichenberg (DE); Frank Feustel, Dresden (DE); Kai Frohberg, Niederau (DE)

(73) Assignee: GLOBAL FOUNDRIES Inc., Grand Cayman (KY)

(21) Appl. No.: 13/237,268

(22) Filed: Sep. 20, 2011

Related U.S. Application Data
(62) Division of application No. 12/176,469, filed on Jul. 21, 2008.

(30) Foreign Application Priority Data
Jan. 31, 2008 (DE) 10 2008 006 960.4

(51) Int. Cl. H01L 21/336; H01L 21/762

(52) U.S. Cl. 438/296; 438/424; 257/E21.546; 257/E21.409

(57) ABSTRACT

By forming an isolation structure that extends above the height level defined by the semiconductor material of an active region, respective recesses may be defined in combination with gate electrode structures of the completion of basic transistor structures. These recesses may be subsequently filled with an appropriate contact material, thereby forming large area contacts in a self-aligned manner without requiring deposition and patterning of an interlayer dielectric material. Thereafter, the first metallization layer may be formed, for instance, on the basis of well-established techniques wherein the metal lines may connect directly to respective “large area” contact elements.

### CROSS-REFERENCE TO RELATED APPLICATION

This is a divisional of co-pending application Ser. No. 12/176,469, filed Jul. 21, 2008.

### BACKGROUND

1. Field of the Disclosure

The present disclosure relates to the field of semiconductor manufacturing, and, more particularly, to the formation of an interconnect structure directly contacting a circuit element with the first metallization level.

2. Description of the Related Art

Semiconductor devices, such as advanced integrated circuits, typically contain a great number of circuit elements, such as transistors, capacitors, resistors and the like, which are usually formed in a substantially planar configuration on an appropriate substrate having formed thereon a crystalline semiconductor layer. Due to the large number of circuit elements and the required complex layout of modern integrated circuits, the electrical connections of the individual circuit elements generally may not be established within the same level on which the circuit elements are manufactured, but require one or more additional “wiring” layers, which are also referred to as metallization layers. These metallization layers generally include metal-containing lines, providing the inner-level electrical connection, and may also include a plurality of inter-level connections, which are also referred to as “vias,” that are filled with an appropriate metal and provide the electrical connection between two neighboring stacked metallization layers.

Due to the continuous reduction of the feature sizes of circuit elements in modern integrated circuits, the number of circuit elements for a given chip area, that is, the packing density, also increases, thereby requiring an even larger increase in the number of electrical connections to provide the desired circuit functionality, since the number of mutual connections between the circuit elements typically increases in an over-proportional way compared to the number of circuit elements. Therefore, the number of stacked metallization layers usually increases as the number of circuit elements per chip area becomes larger, while nevertheless the sizes of individual metal lines and vias are reduced. Due to the moderately high current densities that may be encountered during the operation of advanced integrated circuits, and owing to the reduced feature size of metal lines and vias, semiconductor manufacturers are increasingly replacing the well-known metallization materials, such as aluminum, by a metal that allows higher current densities and, hence, permits a reduction in the dimensions of the interconnections. Consequently, copper and alloys thereof are materials that are increasingly used in the fabrication of metallization layers, due to the superior characteristics in view of resistance against electromigration and the significantly lower electrical resistivity compared to, for instance, aluminum. Despite these advantages, copper also exhibits a number of disadvantages regarding the processing and handling of copper in a semiconductor facility. For instance, copper readily diffuses in a plurality of well-established dielectric materials, such as silicon dioxide, wherein even minute amounts of copper, accumulating at sensitive device regions, such as contact regions of transistor elements, may lead to a failure of the respective device. For this reason, great efforts have to be made to reduce or avoid any copper contamination during the fabrication of the transistor elements, thereby rendering copper a less attractive candidate for the formation of contact plugs, which are in direct contact with respective contact regions of the circuit elements. The contact plugs provide the electrical contact of the individual circuit elements to the first metallization layer, which is formed above an interlayer dielectric material that encloses and passivates the circuit elements.

Consequently, in advanced semiconductor devices, the respective contact plugs are typically formed of a tungsten-based metal in an interlayer dielectric stack, typically comprised of silicon dioxide, that is formed above a corresponding bottom etch stop layer, which may typically be formed of silicon nitride. Due to the ongoing shrinkage of feature sizes, however, the respective contact plugs have to be formed within respective contact openings with an aspect ratio which may be as high as approximately 8:1 or more, wherein a diameter of the respective contact openings may be 0.1 μm or even less for transistor devices of the 65 nm technology. The aspect ratio of such openings is generally defined as the ratio of the depth of the opening to the width of the opening. Consequently, the resistance of the respective contact plugs may significantly restrict the overall operating speed of highly advanced integrated circuits, even though a highly conductive material, such as copper or copper alloys, may be used in the metallization layers. Moreover, sophisticated lithography, etch and deposition techniques may be required for forming the contact plugs, as will be described with reference to FIGS. 1a-1b in more detail.

FIG. 1 a schematically illustrates a top view of a portion of a semiconductor device 100. The semiconductor device 100 comprises a substrate (not shown in FIG. 1a) above which is formed a semiconductor layer (not shown) in and above which circuit elements, such as a transistor and the like, are formed. For convenience, a circuit element in the form of a transistor 150 is illustrated. The transistor 150 may comprise a gate electrode structure 151, sidewalls of which may be covered by a spacer element 152. Laterally adjacent to the gate electrode structure 151, an active region in the form of drain and source regions 153 is provided which may be, in addition to a channel region (not shown), located below the gate electrode structure 151. The active region may be defined by an isolation structure 102, above which a portion of the gate electrode structure 151 may be positioned, thereby defining a contact region 154 in contact with a contact plug or contact element 110. Similarly, one or more contact elements 111 may be provided in the drain or source region 153, wherein, for convenience, only one such contact element 111 is illustrated. It should be appreciated that the contact elements 110, 111 are typically formed in an appropriate interlayer dielectric material which for convenience is not shown in FIG. 1a.

FIG. 1b schematically illustrates a cross-sectional view along the line Ib as shown in FIG. 1a, wherein the semiconductor device 100 is illustrated in a further advanced manufacturing stage. As shown, the semiconductor device 100 comprises a substrate 101, which represents any appropriate carrier material, such as a silicon substrate, a silicon-on-insulator (SOI) substrate and the like. A silicon-based semiconductor layer 103 is formed above the substrate 101 and the isolation structure 102, for instance in the form of a trench isolation, defines an active region 104 in which are positioned the drain and source regions 153, i.e., respective dopant concentrations so as to define respective PN junctions with the remaining portion of the active region 104. Furthermore, metal silicide regions 155 may be formed in the drain and source regions 153, thereby defining a contact region thereof, and on the gate electrode structure 151 including the contact portion 154, thereby also defining a respective contact region for the gate electrode structure 151. Furthermore, the semiconductor device comprises an interlayer dielectric material 115 which typically comprises two or more dielectric layers, such as the layer 115A, which may represent a contact etch stop layer comprised of silicon nitride, and a second dielectric material 115B, for instance provided in the form of a silicon dioxide material. Typically, a thickness 115T of the interlayer dielectric material 115 is in the range of several hundred nanometers. Consequently, the contact element 111 connecting to the drain or source region 153 may have a moderately high aspect ratio, since the lateral size thereof is substantially restricted by the lateral dimension of the drain and source regions 153, while the depth of the contact element 111 is determined by the thickness 115T of the interlayer dielectric material 115. On the other hand, the contact element 110 only has to extend down to the top surface of the gate electrode structure 151, i.e., to the contact portion 154, while the lateral dimension of the contact element 110 may be different compared to the element 111, depending on the size and shape of the contact portion 154. The contact elements 110, 111 typically comprise a barrier material in the form of a titanium liner 112, followed by a titanium nitride liner 113, while the actual fill material 114 may be provided in the form of a tungsten material.

The metallization layer 120 typically comprises an etch stop layer 123, for instance in the form of silicon nitride, silicon carbide, nitrogen-enriched silicon carbide and the like, on which may be formed an appropriate dielectric material 124, such as a low-k dielectric material having a relative permittivity of 3.0 or less. Moreover, respective metal lines 121, 122 are formed in the dielectric material 124 and connect to the contact elements 110, 111, respectively. The metal lines 121, 122 may comprise a copper-containing metal in combination with an appropriate barrier material 125, such as a material comprising tantalum, tantalum nitride and the like. Finally, a cap layer 126 is typically provided to confine the copper material in the metal lines 121, 122, which may be accomplished on the basis of dielectric materials such as silicon nitride, silicon carbide and the like.

A typical process flow for forming the semiconductor device 100 as shown in FIGS. 1a-1b may comprise the following processes. After forming the circuit element 150 on the basis of well-established techniques in accordance with design rules of the respective technology node, which includes forming an appropriate gate insulation layer (not shown) and patterning the same, along with the gate electrode structure 151, by sophisticated lithography and etch techniques, the drain and source regions 153 may be formed by ion implantation, using the spacer structure 152 as an appropriate implantation mask. After any anneal cycles, the metal silicide regions 155 are formed and the interlayer dielectric material is deposited, for instance, by forming the contact etch stop layer 115A, followed by the deposition of silicon dioxide material on the basis of plasma enhanced chemical vapor deposition (PECVD) techniques. After planarizing the resulting surface topography of the silicon dioxide material, a photolithography sequence may be performed, thereby requiring sophisticated recipes with respect to overlay accuracy and defining the lateral size of the openings due to the reduced dimensions, as previously discussed.

Next, anisotropic etch techniques are used for forming contact openings extending through the interlayer dielectric material 115 so as to connect to the gate electrode structure 151 and the drain and source regions 153. During the respective etch process, sophisticated patterning regimes may be required due to the high aspect ratio of the corresponding contact opening, in particular for the contact element 111. During the complex etch sequence, the layer 115A may be used as an etch stop layer for etching the silicon dioxide material 115B, after which a further etch process may be performed in order to finally expose the contact regions in the drain and source regions 153 and the gate electrode structure 151, i.e., the metal silicide regions 155. Next, the titanium nitride liner 112 is formed on the basis of, for instance, physical vapor deposition, such as sputter deposition. After forming the titanium nitride liner 112, the titanium layer 113 may also be formed by sputter deposition wherein, however, the high aspect ratio, in particular in the contact opening corresponding to the contact element 111, may result in an increased layer thickness at sidewall portions so as to accomplish reliable coverage of all exposed surface portions of the contact opening. Thereafter, the tungsten material 114 may be deposited by chemical vapor deposition (CVD) in which tungsten hexafluorine (WF₆) is reduced in a thermally activated first step on the basis of silane and is then converted into tungsten in a second step on the basis of hydrogen. During the reduction of the tungsten on the basis of hydrogen, a direct contact to silicon dioxide of the layer 115B is substantially prevented by the titanium liner 113 in order to avoid undue silicon consumption from the silicon dioxide. On the other hand, the titanium nitride layer 112 may enhance the adhesion of the titanium liner 113, thereby enhancing the overall mechanical stability of the contact elements 110, 111. Thus, the high aspect ratio of the contact element 111 may result in a highly complex etch sequence and a subsequent deposition of the liners 112, 113 which may result in a reduced effective cross-sectional area of the contact element 111, thereby increasing the overall series resistance thereof. On the other hand, any non-uniformities during the complex patterning process including the sophisticated lithography and alignment procedures may result in a contact failure, which may represent one of the dominant factors that contribute to the overall yield loss.

Thereafter, the metallization layer 120 may be formed by depositing the etch stop layer 123, followed by the deposition of the dielectric material 124. Next, respective trenches are formed in the dielectric material 124 according to well-established single damascene strategies. Next, the metal lines 121, 122 may be formed by depositing a barrier layer 125 and filling in a copper-based material, for instance on the basis of electroplating, which may be preceded by the deposition of a copper seed layer. Finally, any excess material may be removed, for instance by chemical mechanical polishing (CMP), and the cap layer 126 may be deposited.

Consequently, the contact structure of the semiconductor device 100 comprises high aspect ratio contacts, such as the contact element 111, resulting in a complex patterning and deposition regime, thereby increasing the probability for reduced production yield, while also contributing to increased resistance and thus reduced electrical performance.

The present disclosure is directed to various methods and devices that may avoid, or at least reduce, the effects of one or more of the problems identified above.

### SUMMARY OF THE DISCLOSURE

The following presents a simplified summary of the disclosure in order to provide a basic understanding of some aspects disclosed herein. This summary is not an exhaustive overview, and it is not intended to identify key or critical elements of the invention or to delineate the scope of the invention. Its sole purpose is to present some concepts in a simplified form as a prelude to the more detailed description that is discussed later.

Generally, the principles disclosed herein relate to techniques and respective semi-conductor devices in which a contact structure may be provided on the basis of significantly less critical manufacturing margins and with enhanced electrical characteristics in view of resistivity. For this purpose, a substantially self-aligned process technique is contemplated in which appropriately designed isolation structures may have protruding portions that may extend above a height level of a semiconductor layer, thereby defining, in combination with respective circuit features such as gate electrode structures, a recess after completing the basic configuration of the circuit elements. These recesses may be subsequently filled with an appropriate contact material, thereby automatically positioning the contact material to connect to the active region without requiring the deposition of an interlayer dielectric material and a corresponding patterning thereof. Hence, contact failures in view of limited overlay accuracy during the patterning of contact openings in conventional strategies may be significantly reduced. Moreover, due to the increased contact area provided by the principles disclosed herein, the resulting contact resistance may be significantly reduced, thereby further contributing to overall performance gain.

One illustrative method disclosed herein comprises forming an isolation structure in and above a semiconductor layer of a semiconductor device, wherein the isolation structure laterally encloses an active region. The method further comprises forming a conductive structure above the active region, wherein the conductive structure comprises an insulating spacer structure formed on sidewalls thereof. Additionally, the method comprises filling a space between the conductive structure and the isolation structure with a conductive contact material that connects to the active region. Finally, the method comprises forming a metallization layer above the conductive contact material and the conductive structure, wherein the metallization layer comprises a dielectric material and a metal line connecting to the conductive contact material.

A further illustrative method disclosed herein relates to the formation of a contact structure of a transistor device. The method comprises defining an active region of the transistor device by forming an isolation structure so as to extend above a semiconductor layer. The method further comprises forming a gate electrode structure above the active region and forming drain and source regions. Additionally, the method comprises filling a first recess and a second recess defined by the isolation structure and the gate electrode structure with a contact material, wherein the first and second recesses connect to the drain and source regions, respectively.

An illustrative semiconductor device disclosed herein comprises an isolation structure defining an active region formed in a semiconductor layer, wherein the isolation structure comprises a protruding portion extending above a height level defined by a surface of the semiconductor layer. The semiconductor device further comprises a conductive line formed above the active region and also comprises a sidewall spacer structure formed on sidewalls of the conductive line. Additionally, the semiconductor device comprises a conductive contact material continuously extending from the protruding portion of the isolation structure to the sidewall spacer structure.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a top view of a conventional semiconductor device comprising contact elements connecting to a gate electrode structure and drain or source regions, according to conventional techniques;

FIG. 1b schematically illustrates a cross-sectional view along the line Ib of FIG. 1a in a further advanced manufacturing stage, wherein high aspect ratio contact elements are provided, according to conventional approaches;

FIGS. 2a-2m schematically illustrate cross-sectional views of a semiconductor device during various manufacturing stages in forming a contact structure and a first metallization layer according to a self-aligned technique, according to illustrative embodiments disclosed herein;

FIG. 2n schematically illustrates a top view of the semiconductor device of FIG. 2m;

FIG. 2o schematically illustrates a cross-sectional view of further embodiments in which additional sidewall spacer elements may be provided so as to finely tune a desired distance of the self-aligned contact structure from the gate electrode structure, according to illustrative embodiments disclosed herein;

FIG. 2p schematically illustrates a cross-sectional view of the semiconductor device according to still further illustrative embodiments in which metal silicide regions may be formed prior to filling in a contact material and optionally prior to forming additional sidewall spacer elements;

FIG. 2q schematically illustrates a cross-sectional view of an embodiment in which metal silicide regions may be created after the deposition of the contact material; and

FIGS. 2r-2s schematically illustrate cross-sectional views of the semiconductor device according to still further illustrative embodiments in which at least a portion of a gate electrode structure may be replaced by a metal-containing material after providing the contact material.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

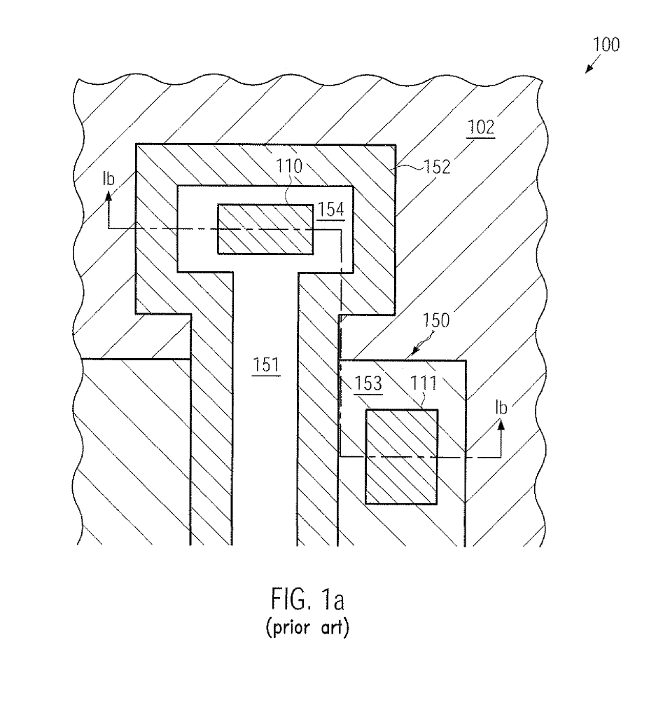

Generally, the principles disclosed herein relate to techniques and respective semiconductor devices wherein an enhanced contact structure may be provided on the basis of a self-aligned manufacturing sequence, thereby substantially eliminating or reducing corresponding limitations with respect to alignment issues occurring in sophisticated lithography processes according to conventional techniques. Furthermore, the deposition and the patterning of a corresponding interlayer dielectric material may, in some illustrative aspects disclosed herein, be avoided, thereby significantly reducing process complexity while at the same time also reducing the probability of the occurrence of contact failures due to deposition- and etch-related irregularities. The self-aligned process technique may be accomplished on the basis of an isolation structure, a portion of which may protrude from the semiconductor material of an active region, thereby creating, in combination with circuit elements such as gate electrode structures, polysilicon lines and the like, well-defined recesses connecting to exposed portions of the active region, wherein the effective size of the recesses, i.e., the space between the circuit elements, such as the gate electrode structures, and the protruding portion of the isolation structures, may be tuned on the basis of sidewall spacer elements which may be used for the profiling of the dopant concentration in the active region, while, in other illustrative embodiments, further spacer elements may be created after the end of respective implantation sequences. By filling the respective recesses or spaces with an appropriate contact material, a “large area” contact element may be created in a self-aligned manner, while additionally the resulting contact resistance may be significantly reduced compared to conventional techniques, as is, for instance, described with reference to FIGS. 1a-1b. After forming the self-aligned contact elements or contact areas, the first metallization layer may be formed in accordance with well-established techniques, wherein the respective metal lines may directly connect to the contact areas, thereby also contributing to enhanced process robustness and a reduced contact resistance from the contact elements to the metal lines of the first metallization layer. Consequently, the contact structure of sophisticated semiconductor devices may be formed without critical lithography and patterning processes while also significantly reducing the overall contact resistance.

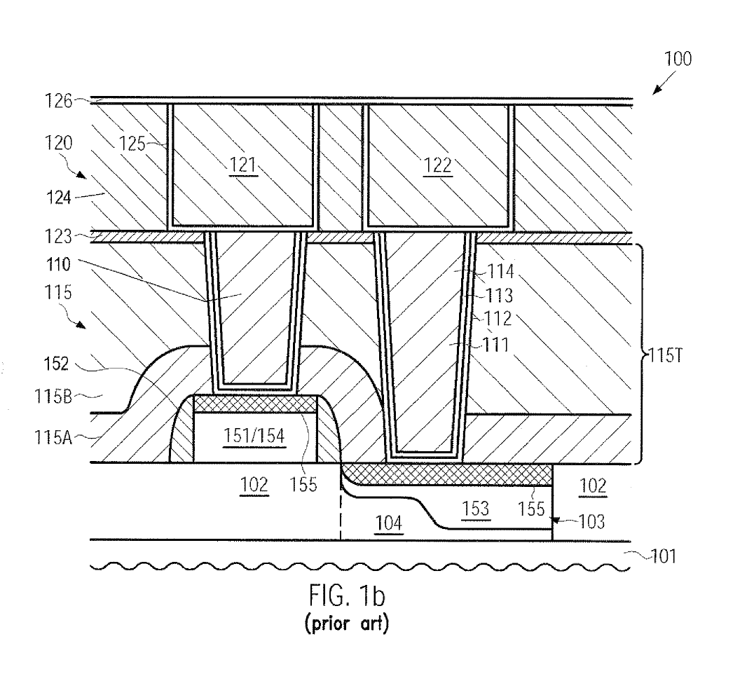

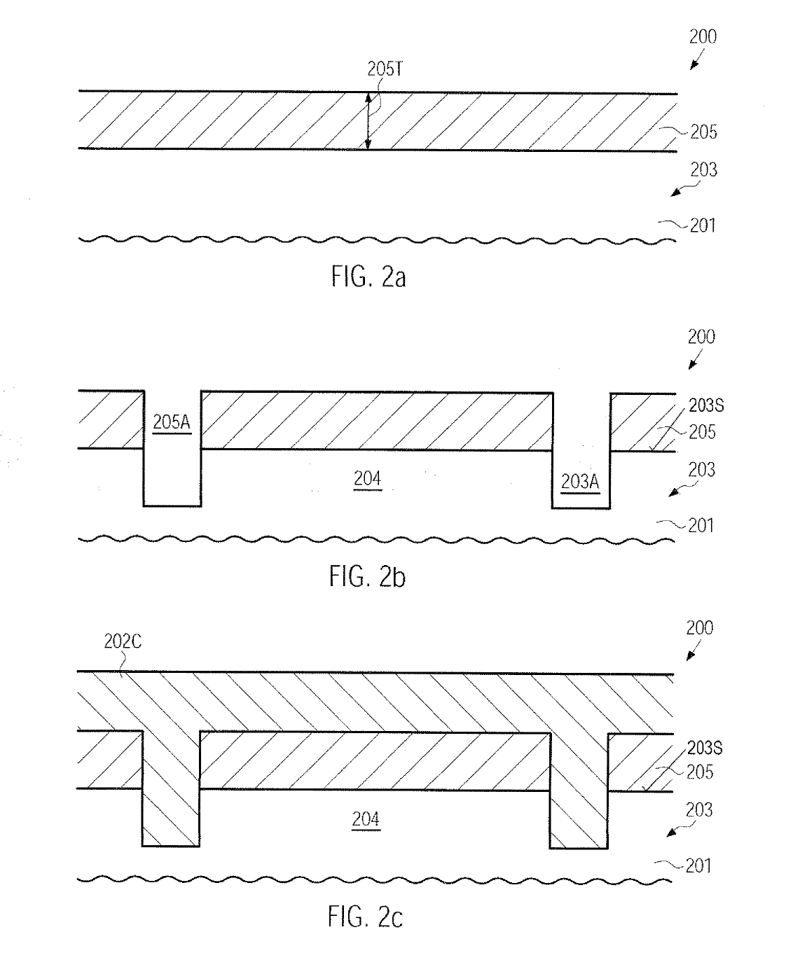

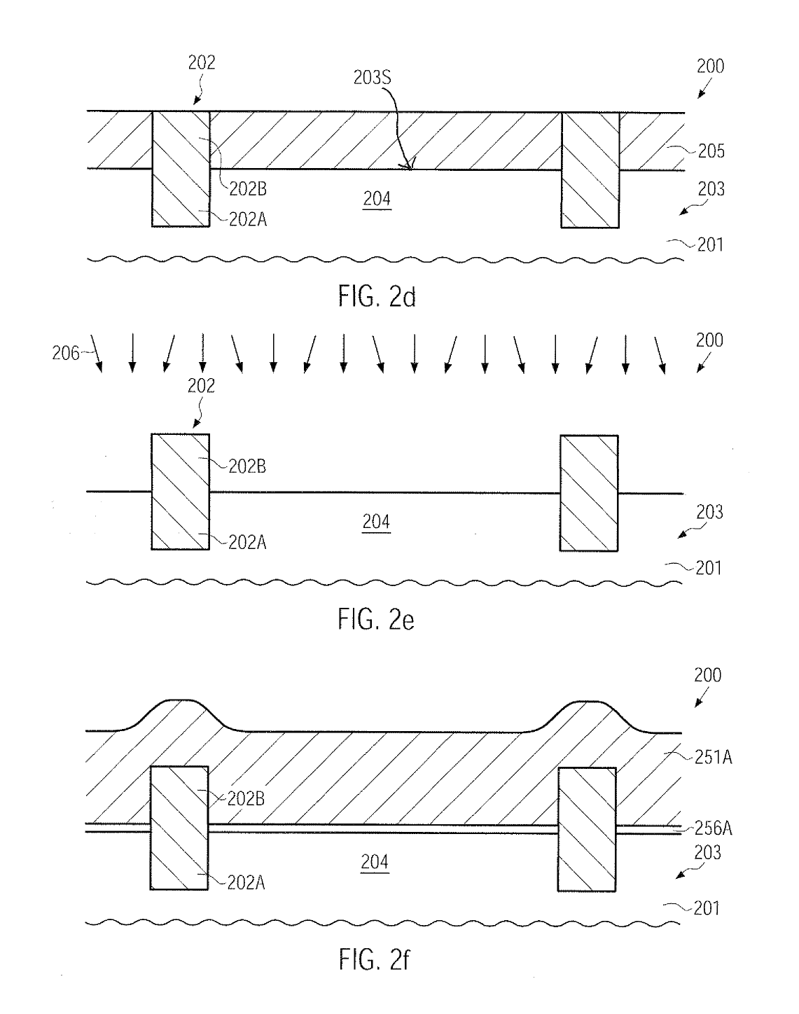

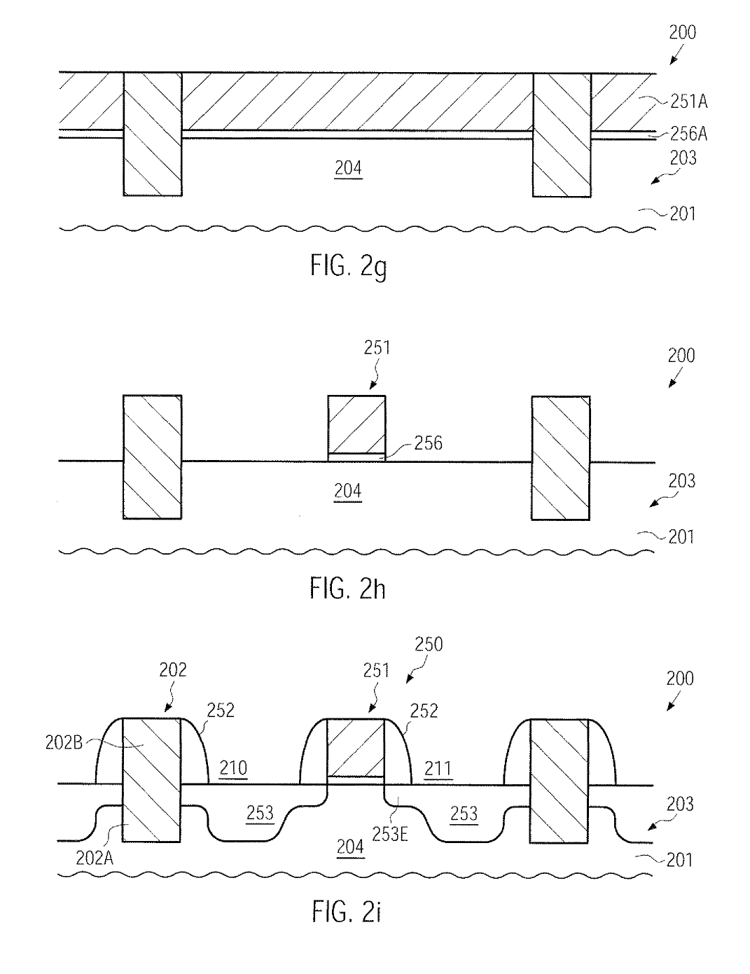

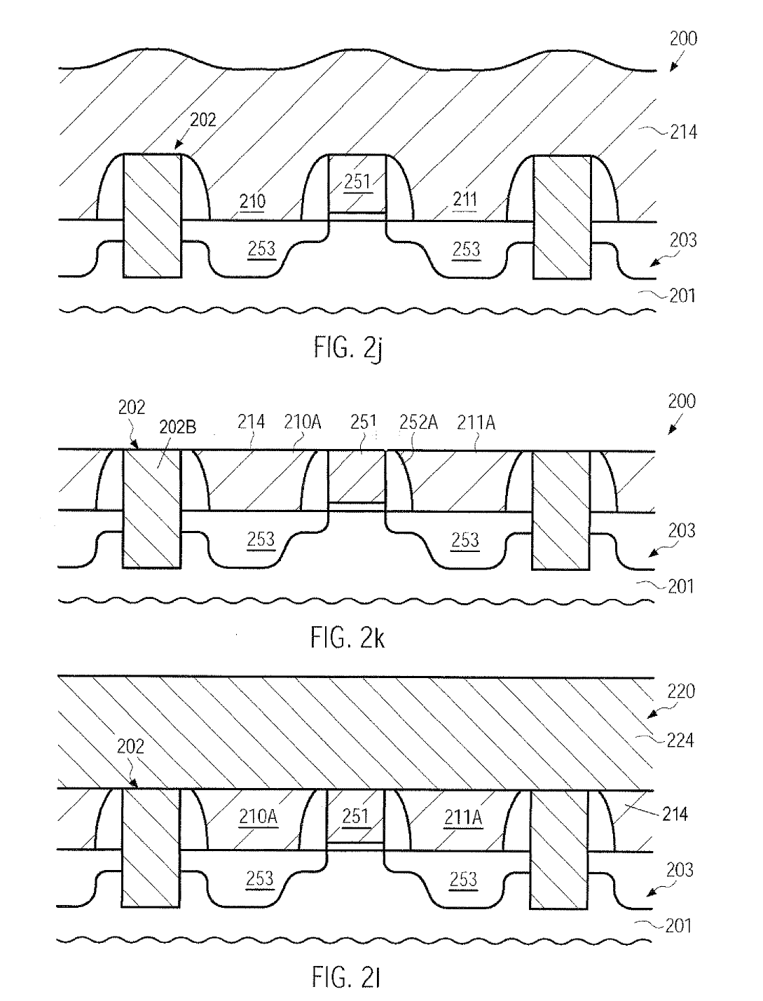

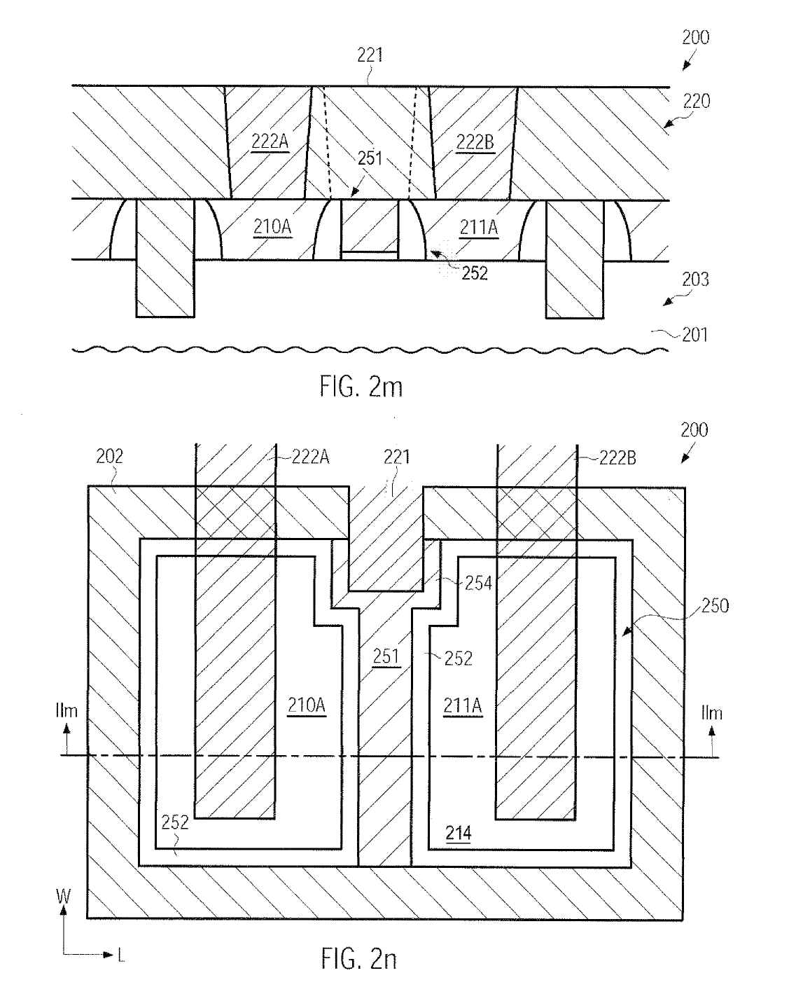

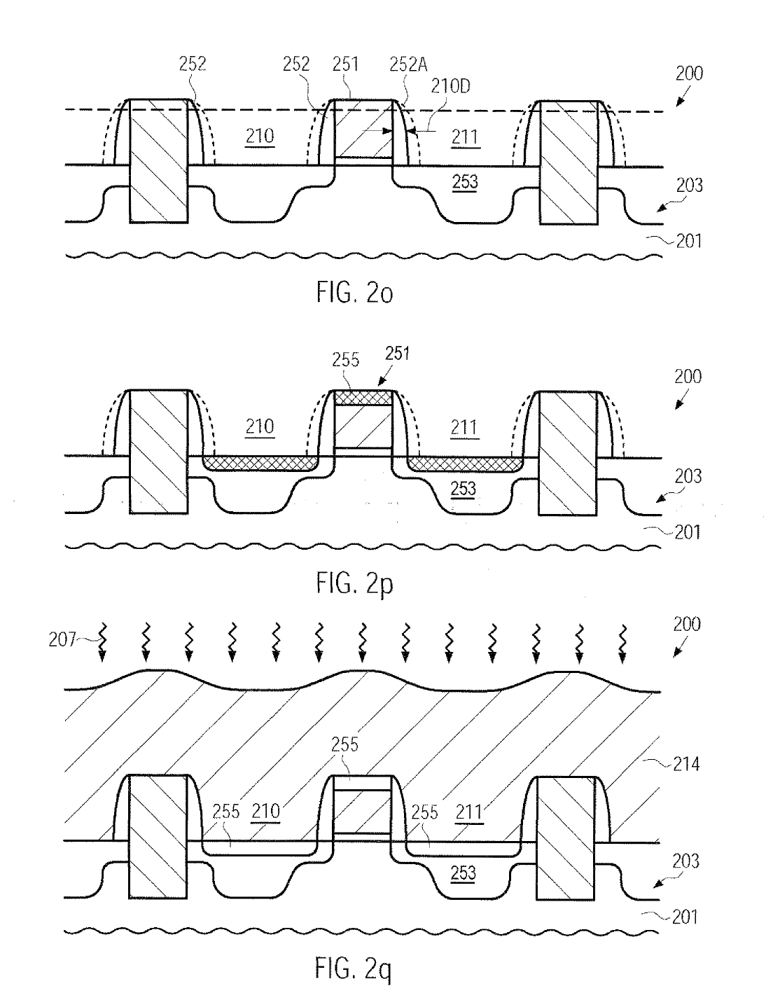

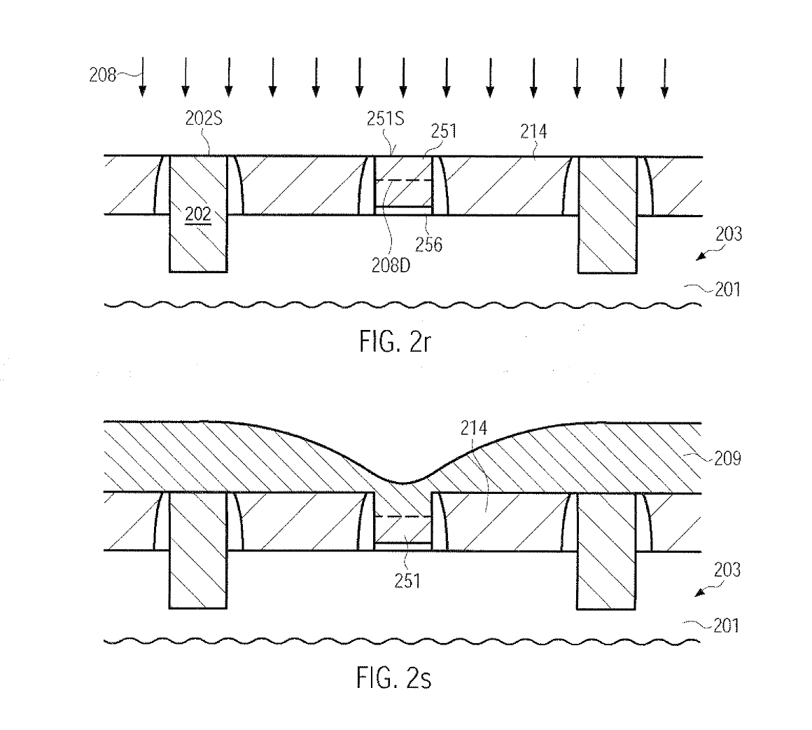

FIG. 2a schematically illustrates a cross-sectional view of a semiconductor device 200 in an early manufacturing stage. As shown, the device 200 may comprise a substrate 201 which may represent any appropriate carrier material for forming thereon or thereabove a semiconductor layer 203. For example, the substrate 201 may represent a semiconductor material, an upper portion of which may represent the semiconductor layer 203, while, in other embodiments, the substrate 201 and the semiconductor layer 203 may define an SOI configuration wherein an insulating layer (not shown) may be provided on which a semiconductor layer 203 may be formed. It should be appreciated that the device 200 may comprise an SOI configuration in some device areas and a bulk configuration in other device areas, if appropriate. Furthermore, the semiconductor device 200 may comprise a sacrificial material layer 205 which may be comprised of any appropriate material that may be selectively removed in a later manufacturing stage. In some illustrative embodiments, the sacrificial material layer 205 may comprise a silicon nitride material, possibly in combination with an etch stop liner (not shown), silicon carbide material, nitrogen-containing silicon carbide, amorphous carbon material, silicon dioxide and the like. In some illustrative embodiments, the sacrificial material layer 205 may be provided with a thickness 205T that may substantially correspond to the height of circuit elements still to be formed above the semiconductor layer 203, such as gate electrode structures and the like. In other examples, the thickness 205T may be less critical since the desired height of a contact structure and respective circuit elements may be adjusted in a later manufacturing stage. For instance, the thickness 205T may be in the range of approximately 50-200 nm, depending on the overall device requirements.

The sacrificial material layer 205 may be formed on the semiconductor layer 203 by any appropriate deposition technique, for instance, thermally activated or plasma assisted CVD techniques, wherein a plurality of well-established process recipes may be used. For example, if enhanced process robustness with respect to a selective removal of the sacrificial material 205 may be required, an appropriate etch stop liner (not shown) may be formed on the semiconductor layer 203 prior to actually providing the sacrificial material 205.

FIG. 2b schematically illustrates the semiconductor device 200 in a further advanced manufacturing stage. That is, the sacrificial material layer 205 and the semiconductor layer 203, or at least a portion thereof, may have formed therein trenches 205A, 203A, respectively, wherein, in some illustrative embodiments, the trenches 205A, 203A may represent isolation trenches as required for forming a trench isolation structure. A process sequence for forming the trenches 205A, 203A may, in some illustrative embodiments, comprise well-established photolithography techniques for forming a resist mask above the sacrificial layer 205, for instance by providing appropriately selected anti-reflective coating (ARC) materials in combination with a resist material and exposing and developing the resist material. It should be appreciated that, in some cases, an appropriate ARC material may be included in the sacrificial layer 205. Thereafter, the layer 205 may be patterned on the basis of the resist mask and the further patterning of the semiconductor layer 203 may be accomplished on the basis of the sacrificial layer 205, which may now act as a hard mask layer. For example, selective anisotropic etch techniques may be used for etching through a silicon nitride material of the layer 205 when comprised of silicon nitride, and the etch chemistry may be appropriately changed so as to efficiently etch into the semiconductor layer 203 while using the opening 205A as an etch mask. In other cases, a respective ARC material may be patterned first and may be used as a hard mask for patterning the sacrificial layer 205 and subsequently the semiconductor layer 203. It should be appreciated, however, that any other patterning regime may be used for creating the trenches 205A, 203A. Thus, the trenches 205A, 203A may define an active region 204 in and above which respective circuit elements, such as transistors and the like, are to be formed in a later manufacturing stage. Hence, the isolation trenches 205A, 203A may laterally enclose the active region 204 wherein, in some illustrative embodiments, when an SOI configuration is considered, at least locally, the trenches 205A, 203A may extend at least to a corresponding buried insulating layer, thereby providing a substantially complete dielectric isolation of the active region 204 with respect to other device areas. In other cases, the trenches 205A, 203A may extend into the semiconductor layer 203 according to a specified depth.

FIG. 2c schematically illustrates the semiconductor device 200 in a further advanced stage in which an insulating fill material 202C may be provided within the trenches 205A, 203A and above horizontal portions of the device 200. The insulating fill material 202C may be comprised of any appropriate dielectric material having a desired high etch selectivity with respect to the sacrificial layer 205. For instance, the fill material 202C may be provided in the form of silicon dioxide material, thereby providing a high degree of process compatibility with conventional manufacturing sequences. In other illustrative embodiments, any other appropriate material, such as silicon nitride, silicon carbide and the like, may be used as long as a required compatibility with subsequent manufacturing processes as well as the desired etch selectivity may be provided. The fill material 202C may be deposited on the basis of any appropriate deposition technique, such as a thermally activated CVD process for forming silicon dioxide, plasma assisted CVD processes, if the desired gap fill capabilities are provided by the deposition technique under consideration, and the like.

FIG. 2d schematically illustrates the semiconductor device 200 after the removal of excess material of the fill material 202C, thereby defining an isolation structure 202 having a portion 202A within the semiconductor layer 203 and a protruding portion 202B that extends above a surface 203S of the semiconductor layer 203 corresponding to a height level as defined by the thickness of the sacrificial layer 205. The removal of excess material may be accomplished by performing a CMP process and/or any other planarization technique, including selective etch processes and the like.

FIG. 2e schematically illustrates the semiconductor device 200 during a selective etch process 206 that is designed to selectively remove the sacrificial material 205 with respect to the isolation structure 202 and with respect to the semiconductor material 203. As previously explained, in some illustrative embodiments, an etch stop liner may be used during the etch process 206, which may, therefore, avoid undue damage of the exposed surface of the semiconductor layer 203 at the final phase of the etch process 206. In this case, an additional etch step may be performed to remove the optional etch stop liner. For instance, if the sacrificial layer 205 may be provided in the form of a silicon nitride material, a respective silicon dioxide liner may be provided and may be removed selectively to the semiconductor layer 203. A corresponding material removal of the protruding portion 202B may be less critical since the etch stop liner may be provided with a thickness of several nanometers so that a comparable material removal in the portion 202B may not substantially affect the further processing.

FIG. 2f schematically illustrates the semiconductor device 200 after the deposition of a conductive material 251A which may be used for forming a circuit element above the active region 204 and within the area enclosed by the isolation structure 202. In one illustrative embodiment, the conductive material 251A may be provided in the form of an appropriate material for forming gate electrode structures and/or conductive line elements, wherein, for instance, polysilicon material may be used, as is frequently employed for the formation of advanced field effect transistors. Furthermore, prior to the deposition of the conductive material 251A, an appropriate insulation layer 256A may be formed, for instance, on the basis of deposition and/or oxidation, possibly in combination with any other techniques for adjusting a thickness and dielectric characteristics of the layer 256A. For instance, the layer 256A may act as a gate insulation layer in a later stage and hence respective well-established process techniques may be used for forming the layer 256A having the desired characteristics. In some illustrative embodiments, well-established process recipes may be used, as also previously described with reference to the device 100. For example, polysilicon material may be deposited by low pressure CVD techniques while, in other cases, metal-containing materials may be used, possibly in combination with high-k dielectric materials, for the insulation layer 256A.

FIG. 2g schematically illustrates the semiconductor device 200 after planarizing the conductive material 251A, thereby providing a substantially planar surface topography which may be appropriate for a subsequent sophisticated photolithography process for patterning the conductive material 251A. The planarization may be performed on the basis of CMP and/or appropriate etch techniques. Thereafter, a mask layer may be formed on the basis of photolithography and the material 251A may be patterned on the basis of the mask layer, which may include the provision of a hard mask material and the like.

FIG. 2h schematically illustrates the semiconductor device 200 after the above-described patterning sequence. As shown, the device 200 may now comprise a conductive element 251, such as a gate electrode and the like, which may be formed on the insulation layer 256 so as to separate the conductive element 251 from the active region 204.

FIG. 2i schematically illustrates the semiconductor device 200 in a further advanced manufacturing stage. As illustrated, a dopant profile may be established within the active region 204, which, in some illustrative embodiments, may represent the dopant profile of drain and source regions 253 of a transistor element 250. Moreover, a sidewall spacer structure 252 may be formed on sidewalls of the conductive element 251, which may also be referred to as gate electrode 251 if the circuit element 250 represents a field effect transistor. Furthermore, the sidewall spacer structure 252 may also be formed on sidewalls of the isolation structure 202, that is, the protruding portion 202B thereof may now be comprised of the initial portion as shown in the previous figures and the spacer structure 252.

A typical process flow for forming the device 200 as shown in FIG. 2i may comprise the following processes. After patterning of the conductive element 251, extension regions 253E may be formed on the basis of appropriate implantation techniques wherein, if required, a respective offset spacer (not shown) may be formed on sidewalls of the conductive element 251. Thereafter, one or more individual spacer elements of the structures 252 may be formed by depositing an appropriate material, such as a silicon nitride material, and removing any excess material by well-established etch techniques. Depending on the complexity of the lateral profile in the regions 253, intermediate implantation processes may be performed until the final dopant concentration is achieved. Thereafter, anneal processes may be performed, as also previously explained, so as to activate dopant atoms and re-crystallize implantation-induced damage. In some illustrative embodiments, the further processing may be continued by forming metal silicide regions, as will be described later on in more detail. In other illustrative embodiments, the processing may be continued by depositing an appropriate conductive contact material to fill spaces or recesses 210, 211 defined by the conductive element 251 and the corresponding sidewall spacer structure 252 and the protruding portion 202B, which may comprise the sidewall spacer structure 252.

FIG. 2j schematically illustrates the semiconductor device 200 with a contact material 214 formed in the recesses 210, 211 and above the isolation structures 202 and the conductive line 251. The contact material 214 may represent any appropriate conductive material, such as a metal-containing material suitable for connecting to the drain and source regions 253 while also being compatible with other device requirements and with the further processing of the device 200. For example, as previously explained with reference to the semiconductor device 100, in many cases, an appropriate conductive barrier material may be provided to enhance the overall performance of respective contact elements in view of the deposition characteristics for the contact material, the adhesion thereof, the interaction with surrounding materials and the like. For example, in some illustrative embodiments, well-established contact metal deposition regimes may be used, for instance, by forming one or more appropriate barrier materials, such as titanium, titanium nitride and the like, in combination with a tungsten material, as is also previously explained with reference to the device 100. It should be appreciated, however, that, contrary to the conventional deposition regime described with reference to the device 100, significantly relaxed deposition conditions may be encountered since the aspect ratios of the recesses 210, 211 may be significantly less compared to the aspect ratios of the contact elements 110, 111, as previously discussed.

In other illustrative embodiments, any other appropriate metal-containing material may be used, for instance, highly conductive materials such as nickel, platinum, copper, silver and the like, possibly in combination with appropriate barrier materials. In still other illustrative embodiments, a mixture of different metals may be used, for instance, by providing a moderately thick well-established contact material, such as tungsten, possibly in combination with respective barrier materials, followed by a highly conductive material, such as copper, in combination with an appropriate barrier material such as tantalum, tantalum nitride and the like. For this purpose, the contact material 214 may be deposited on the basis of any appropriate deposition technique, for instance, by providing an appropriate liner material, followed by the deposition of the desired first portion of the contact material, such as tungsten, as previously explained, followed by the deposition of a further barrier material. Thereafter, a highly conductive metal, such as copper and the like, may be deposited by electrochemical deposition techniques for which well-established recipes may be available, wherein, also in this case, significantly relaxed process conditions may be encountered due to the previously deposited material and the reduced aspect ratio of the recesses 210, 211. In still other illustrative embodiments, an appropriate metal may be deposited by an electrochemical deposition process after the provision of appropriate barrier and seed materials, for example, nickel, copper and the like, may be deposited in a highly efficient manner, wherein appropriate barrier materials such as tantalum, tantalum nitride and the like may provide a required confinement of the metal if critical metals, such as copper, are used.

FIG. 2k schematically illustrates the semiconductor device 200 in an advanced manufacturing stage in which excess material of the contact material 214 is removed by any appropriate planarization technique, which may include etch processes, CMP processes, electrochemical processes and the like. In some illustrative embodiments, at least in a final phase of the planarization process, a CMP process may be used to reliably remove any residues of the contact material 214 from exposed surface areas of the conductive element 251 and the isolation structures 202. For example, a substantially non-selective CMP process may be carried out, thereby not only removing material of the contact material 214 but also reducing the height of the element 251 and the isolation structures 202 to a certain degree so as to obtain a desired final height and also reliably electrically insulate a first contact element 211A from a second contact element 210A. It should be appreciated that a certain degree of “dishing” in the first and second contact elements 210A, 211A may not negatively affect the further processing and the characteristics of the contact elements 210A, 211A but may enhance the overall reliability and process robustness for ensuring dielectric isolation of the elements 210A, 211A. Thus, the semiconductor device 200 may comprise a contact structure comprising the contact elements 210A, 211A connecting to the drain and source regions 253, respectively, wherein the elements 210A, 211A may continuously extend from the protruding portion 202B which may include the spacer structure 252 to the sidewall spacer structure 252 at the conductive line 251, thereby providing a large contact area with the drain and source regions 253, which may result in a significantly reduced contact resistance. The distance between the contact elements 210A, 211A and the conductive line 251, which may represent a gate electrode structure, may be defined by the sidewall spacer structure 252, wherein also a certain degree of adjusting the distance may be accomplished by removing a tip portion of the spacers 252 during the removal of the excess material of the contact material 214.

FIG. 21 schematically illustrates the semiconductor device 200 in an advanced manufacturing stage in which a dielectric material 224 of a first metallization layer 220 is formed above the contact elements 211A, 210A and the line element 251 and the isolation structures 202. The dielectric material 224 may comprise a low-k dielectric material, as previously explained, possibly in combination with an etch stop material, if required. For example, if the contact material 214 may comprise a critical metal, such as copper and the like, an insulating barrier material such as silicon carbide, nitrogen-containing silicon carbide, silicon nitride and the like may be formed prior to the deposition of the dielectric material 224 so as to effectively confine the metal in the contact elements 210A, 211A. In other illustrative embodiments, when a direct contact of a low-k dielectric material with the metal of the contact elements 210A, 211A may be considered appropriate, a respective dielectric barrier layer may be omitted. The dielectric material 224 may be formed on the basis of any appropriate deposition technique so as to provide the desired material characteristics. Next, the dielectric layer 224 may be patterned on the basis of well-established patterning recipes, wherein, in some illustrative embodiments, well-established techniques according to conventional strategies, as previously explained with reference to the device 100, may be used. Hence, a high degree of process compatibility with conventional strategies may be achieved. In other cases, the dielectric material 224 may be patterned according to any appropriate patterning regime including lithography, such as photolithography, imprint techniques and the like. The patterning of the dielectric material 224 may be performed such that appropriate trenches for metal lines are created which may extend down to the contact elements 210A, 211A, depending on the required circuit layout. During the corresponding anisotropic etch processes, the conductive material 214 in the contact areas 210A, 211A may itself act as an etch stop material and/or a further etch stop material may be provided, as previously explained. Thereafter, the respective trenches may be filled with an appropriate material, such as copper-based materials in combination with suitable barrier materials, as previously explained.

FIG. 2m schematically illustrates the semiconductor device 200 after the end of the above-described process sequence. Hence, the metallization layer 220 may comprise a plurality of metal lines 222A, 222B, 221 comprising an appropriate metal, such as copper, copper alloys, aluminum and the like, possibly in combination with appropriate barrier materials (not shown) to provide confinement of the metal if a direct contact with other device materials may not be considered appropriate. In the embodiment shown, the metal line 222A may directly connect to the contact element 210A, while the metal line 222B may connect to the contact element 211A. It should be understood that a “direct contact” in this sense is an electrical connection from the metal lines 222A, 222B to the respective contact element 210A, 211A without an intermediate “via.” Thus, a reduced contact resistance between the metal lines 222A, 222B and the contact elements 210A, 211A may be obtained since a connection between these components may be provided continuously along a width direction of the device 200, i.e., in FIG. 2m, a direction perpendicular to the drawing plane of FIG. 2m. Similarly, the metal line 221, indicated as dashed lines, may connect to a contact area of the conductive line or gate electrode 251, similarly as is shown in FIGS. 1a-1b. Consequently, during the patterning of the respective trenches for the metal lines 222A, 222B and 221, less critical constraints with respect to overlay accuracy may be accomplished since the contact elements 210A, 211A continuously extend along substantially the entire length direction of the device 200, i.e., in FIG. 2m, the horizontal direction except for portions covered by the conductive line or gate electrode 251 and the sidewall spacer structures 252.

FIG. 2n schematically illustrates a top view of the semiconductor device 200 as shown in FIG. 2m wherein, for convenience, the dielectric material 224 of the metallization layer 220 and the metal lines 222A, 222B may be considered as “transparent” so as to reveal the underlying components. As illustrated, the isolation structure 202 may define, with its lower portion 202A (not shown), the active region 204, while the upper portion 202B, including the sidewall spacer structure 252, may define, in combination with the line element 251 and the respective spacer structure 252, the lateral size of the contact elements 210A, 211A. Thus, the contact material 214 may continuously cover the portion of the drain and source regions 253 (not shown) that is not covered by the sidewall spacer structure 252 and the conductive line 251. Moreover the conductive lines 222A, 222B extend along a significant portion of the width direction W, thereby providing a low contact resistance, while alignment accuracy in the length direction L may be less critical due to the continuous provision of the contact elements 210A, 211A along this direction. Moreover, the metal line 221 may directly connect to a contact portion 254 of the conductive line 251, wherein the contact portion 254 may also be located within the area enclosed by the isolation structure 202. Hence, a connection between conductive lines 251 of adjacent active regions may be established by means of the first metallization layer 220, thereby providing low resistance connection due to the superior conductivity of a metal in the metal line 221 compared to, for instance, polysilicon connections in conventional devices which may not comprise the protruding portion of the isolation structure 202.

Consequently, a significantly reduced process complexity may be achieved by the semiconductor device 200 as shown in FIG. 2n, since the deposition of a dielectric interlayer material for the contact structure and the corresponding patterning of contact openings therein may be eliminated. That is, the failure-prone alignment procedures and the complex patterning regime of conventional devices may be avoided, thereby significantly enhancing the overall production yield, as the process of forming contact elements may represent one of the most critical process phases. Additionally, the substantially complete coverage of that portion of the active region 204 that is not covered by the conductive line 251 and the sidewall spacer structure 252 may contribute to a reduced contact resistance, wherein a desired distance between the contact elements 210A, 211A from the conductive line 251 may be adjusted on the basis of the width of the spacer structure 252.

FIG. 2o schematically illustrates a cross-sectional view of the device 200 according to further illustrative embodiments in which an offset or lateral distance 210D of the conductive line 251 or gate electrode structure from the contact elements 210A, 211A (FIG. 2m) may be re-adjusted after completion of the basic transistor structure by forming an additional spacer element 252A, as indicated by the dashed lines. Thus, the distance 210D may be decoupled from any requirements of spacer width in view of profiling the lateral dopant concentration in the drain and source regions 253. For this purpose, after completing the basic transistor structure, an appropriate spacer layer, for instance comprised of silicon nitride, silicon dioxide and the like, possibly in combination with an etch stop layer, may be deposited with an appropriate thickness, followed by an appropriately designed etch process for forming the additional spacers 252A. Thereafter, the further processing may be continued by filling in the recesses 210, 211, having the reduced dimension due to the increased offset 210D, with an appropriate contact material, as previously described.

FIG. 2p schematically illustrates the semiconductor device 200 according to further illustrative embodiments in which, prior to the deposition of the contact material, the conductivity of the drain and source areas 253 and the gate electrode 251 may be enhanced by providing metal silicide regions 255. For this purpose, in one illustrative embodiment, well-established silicidation regimes may be used, i.e., depositing a refractory metal, such as cobalt, nickel, platinum and the like, and initiating a chemical reaction with the underlying silicon-based material. Thereafter, any non-reacted metal material may be removed, possibly followed by a further anneal process for thermally stabilizing the metal silicide regions 255. Thereafter, the further processing may be continued by depositing the material 214, as previously described. In still other illustrative embodiments, the metal silicide regions 255 may be formed on the basis of the spacer structure 252, and thereafter the additional spacer 252A may be formed if a reduced offset 210D may be considered appropriate, as previously explained with reference to FIG. 2o. In still other illustrative embodiments, the spacers 252 may be reduced in the width and/or height or may even be substantially completely removed, except for a respective etch stop liner, so as to more closely position the metal silicide regions 255 to the PN junctions of the drain and source regions 253 or the respective extension regions 253E (FIG. 2i). Thereafter, the additional spacer 252A may be formed in order to re-adjust a desired offset 210D, as previously explained with reference to FIG. 2o. Thus, the lateral extension of the metal silicide regions 255 in the drain and source regions 253 may be adjusted with a high degree of flexibility, while nevertheless providing high process robustness with respect to appropriately positioning the contact elements 210A, 211A with respect to the gate electrode 251.

FIG. 2q schematically illustrates a cross-sectional view of the device 200 in accordance with further illustrative embodiments, in which the contact resistance may be reduced after filling the recesses 210, 211. As illustrated, the device 200 may comprise the contact material 214, which may include an appropriate metal for reacting with silicon material in the drain and source regions 253. For example, in some illustrative embodiments, tungsten, nickel, platinum and the like may be used, at least in the lower portion of the contact material 214, so as to enable a silicidation reaction during a heat treatment 207. For example, nickel material, possibly in combination with platinum, may be deposited, followed by tungsten or any other appropriate material, or a substantially pure nickel layer may be provided and subsequently subjected to the heat treatment 207 in order to initiate a chemical reaction between a lower portion of the metal in the layer 214 and the drain and source regions 253, so as to create the metal silicide regions 255. Similarly, the gate electrode 251 may also receive a metal silicide 255 in its upper portion. Thereafter, the further processing may be continued by removing excess material of the layer 214, as previously described, and forming the metallization layer 220 (FIG. 21).

With reference to FIGS. 2r-2s, further illustrative embodiments will now be described, in which at least a portion of the conductive line or gate electrode 251 may be removed and may be replaced by a metal-containing material, thereby enhancing the overall conductivity of the line 251.

FIG. 2r schematically illustrates the device 200 in a manufacturing stage in which the contact material 214 may have been planarized so as to expose the surface portions 251 S and 202S of the conductive line 251 and the isolation structure 202. For this purpose, similar process techniques may be used as previously discussed. Next, the device 200 is exposed to an etch process 208 that is designed to remove material of the conductive line 251. For example, the line element 251 may be comprised of polysilicon, wherein, in some illustrative embodiments, a metal silicide portion may also be formed therein when corresponding metal silicide regions may have been formed in the drain and source areas as well as the conductive line 251 in an earlier manufacturing stage prior to the deposition of the material 214, as previously described. In other cases, any optional metal silicide region may have been removed during the final phase of the polishing process for planarizing the material 214. Hence, also in this case, the exposed surface portion 251S may be comprised of polysilicon material. Thus, in some illustrative embodiments, the etch process 208 may be designed to selectively remove silicon material with respect to the isolation structures 202, for which well-established etch recipes may be used, as may also be employed during the patterning of polysilicon gate electrode structures, as previously explained. In other illustrative embodiments, the etch process 208 may be performed on the basis of an etch chemistry, which may also exhibit a moderately high selectivity with respect to the material 214, wherein a certain amount of material removal of the contact elements 210A, 211A (FIG. 2k) may be tolerable since the corresponding recesses may be subsequently refilled by an appropriate metal-containing material. Consequently, during the etch process 208, material of the line 251 may be removed to a desired depth, as indicated by 208D.

FIG. 2s schematically illustrates the device 200 in a further advanced manufacturing stage in which a metal-containing material 209 may be formed so as to fill the recess in the conductive line 251, thereby providing an increased conductivity thereof. The metal-containing material 209 may be provided in any appropriate form, for instance, substantially the same material may be used as is also used in the contact material 214 or one or more different materials may be deposited, for instance, by chemical vapor deposition, sputter deposition, electrochemical deposition and the like. Thereafter, any excess material of the layer 209 may be removed, for instance, by etching and/or CMP, as also previously explained with reference to the contact material 214, and thereafter the metallization layer 220 (FIG. 21) may be formed in accordance with techniques as previously described. Hence, the overall conductivity of the line 251 may be increased by providing a desired amount of the conductive material 209.

As a result, the principles disclosed herein provide semiconductor devices and manufacturing techniques in which a contact structure may be formed in a self-aligned manner, without requiring the deposition and patterning of an interlayer dielectric material while additionally providing reduced contact resistance. For this purpose, an isolation structure may be appropriately formed so as to extend above a semiconductor layer to define an inner region in which circuit elements, such as gate electrodes and the like, may be formed. Hence, the isolation structure, in combination with the circuit elements, may define respective recesses, which may be filled with an appropriate contact material after the completion of the basic transistor structures.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
forming an isolation structure in and above a semiconductor layer of a semiconductor device, said isolation structure laterally enclosing an active region;
forming a conductive structure above said active region, said conductive structure comprising an insulating spacer structure on sidewalls thereof;
filling a space between said conductive structure and said isolation structure with a conductive contact material, said conductive contact material connecting to said active region;
after filling said space with said conductive contact material, forming a metal silicide in said active region; and
forming a metallization layer above said conductive contact material and said conductive structure, said metallization layer comprising a dielectric material and a metal line connecting to said conductive contact material.

2. The method of claim 1, wherein forming said isolation structure comprises forming an isolation trench in said semiconductor layer and an isolation feature extending from said isolation trench.

3. The method of claim 2, wherein forming said isolation structure comprises forming a sacrificial material above said semiconductor layer, patterning said sacrificial material and said semiconductor layer so as to form said isolation trench, filling said isolation trench and removing said sacrificial material so as to form said isolation feature.

4. The method of claim 1, wherein forming said conductive structure comprises depositing a conductive material above said semiconductor layer and said isolation structure, planarizing said conductive material and patterning said planarized conductive material.

5. The method of claim 1, wherein filling said space with said conductive contact material comprises depositing said conductive contact material and removing excess material by performing a planarization process to expose a top surface of said conductive structure and of said isolation structure.

6. The method of claim 4, further comprising forming said sidewall spacer structure and performing an implantation process using said sidewall spacer structure as an implantation mask so as to define a lateral dopant profile in said active region.

7. The method of claim 6, further comprising forming a further spacer element after defining said lateral dopant profile and prior to filling said space with said conductive contact material.

8. The method of claim 5, further comprising removing at least a portion of said conductive structure and depositing a metal-containing material.

9. The method of claim 1, wherein said conductive structure represents a gate electrode structure of a transistor element.

10. (canceled)

11. A method for forming a contact structure of a transistor device, the method comprising:
defining an active region of said transistor device by forming an isolation structure so as to extend above a semiconductor layer;
forming a gate electrode structure above said active region;
forming drain and source regions;
filling a first recess and a second recess defined by said isolation structure and said gate electrode structure with a contact material, said first and second recesses connecting to said drain and source regions, respectively; and
after filling said first and second recesses with said contact material, forming a metal silicide in said drain and source regions.

12. The method of claim 11, further comprising forming at least one sidewall spacer element on sidewalls of said gate electrode structure and using said at least one side-wall spacer element for defining a lateral dopant profile of said drain and source regions.

13. The method of claim 12, further comprising forming at least one further side-wall spacer element on said at least one sidewall spacer element after defining said lateral dopant profile.

14. The method of claim 11, wherein forming said isolation structure comprises forming a trench in a sacrificial material layer located above said semiconductor layer and filling said trench with an insulating material.

15. The method of claim 14, further comprising removing said sacrificial material selectively with respect to said insulating material.

16-18. (canceled)

19. The method of claim 11, further comprising replacing a portion of said gate electrode structure by a metal-containing material after filling said first and second recesses.

20-25. (canceled)

26. The method of claim 1, wherein filling said space with said conductive contact material comprises depositing a conductive contact material comprising a refractory metal.

27. The method of claim 26, wherein depositing said conductive contact material comprising said refractory metal comprises forming a layer of said refractory metal on said active region.

28. The method of claim 26, wherein forming said metal silicide comprises performing a heat treatment to initiate a chemical reaction between said refractory metal comprising said conductive contact material and material of said semiconductor layer

29. The method of claim 11, wherein filling said first and second recesses with said contact material comprises depositing a contact material comprising a refractory metal.

30. The method of claim 29, wherein depositing said contact material comprising said refractory metal comprises depositing a layer of said refractory material on said source and drain regions, and wherein forming said metal silicide comprises performing a heat treatment to initiate a chemical reaction between said refractory metal comprising said contact material and material of said semiconductor layer.
